(19) United States
(12) Patent Application Publication
(10) Pub. No.: US 2022/0310523 A1
(43) Pub. Date: Sep. 29, 2022

(54) SEMICONDUCTOR DEVICE

(71) Applicant: SONY SEMICONDUCTOR SOLUTIONS CORPORATION, Atsugi-shi (JP)

(72) Inventors: Yusuke HASHIGUCHI, Atsugi-shi (JP); Yasushi ONO, Atsugi-shi (JP); Seiichiro FUKAI, Atsugi-shi (JP)

(73) Assignee: SONY SEMICONDUCTOR SOLUTIONS CORPORATION, Atsugi-shi (JP)

(21) Appl. No.: 17/616,807

(22) PCT Filed: Jun. 5, 2020
(86) PCT No.: PCT/JP2020/022255

§ 371 Date: Dec. 6, 2021

(30) Foreign Application Priority Data
Jun. 14, 2019 (JP) 2019-110760

(51) Int. Cl. H01L 23/538; H01L 25/065

(52) U.S. Cl. CPC H01L 23/5386; H01L 25/0657; H01L 2225/0651; H01L 2225/06565

(57) ABSTRACT

A semiconductor device according to one embodiment of the present disclosure includes: a first semiconductor chip; a second semiconductor chip stacked on the first semiconductor chip via a spacer; a first terminal group provided around a stacked body in which the first semiconductor chip and the second semiconductor chip are stacked, and coupled to the first semiconductor chip; a second terminal group provided on an outer side of the first terminal group, and coupled to the second semiconductor chip; and a package member that seals the first semiconductor chip, the second semiconductor chip, the first terminal group, and the second terminal group, and in which at least the first terminal group and the second terminal group are exposed on a back face.

### TECHNICAL FIELD

The present disclosure relates to a semiconductor device in which a plurality of semiconductor chips is stacked.

### BACKGROUND ART

In recent years, a digital broadcast receiver has been increasingly equipped with a plurality of tuners and a plurality of demodulation functions. In order to address multiple systems, it is necessary to dispose a plurality of corresponding semiconductor chips, and the mounting area tends to become large accordingly. In contrast, for example, Patent Literature 1 discloses a semiconductor device that has achieved a space-saving by stacking a plurality of semiconductor elements on an interposer.

### CITATION LIST

### Patent Literature

Patent Literature 1: Japanese Unexamined Patent Application Publication No. 2012-175009

### SUMMARY OF THE INVENTION

Incidentally, what is desired for a digital broadcast receiver having a plurality of demodulation functions as described above is to reduce a development period as well as to reduce the mounting area.

It is desirable to provide a semiconductor device that makes it possible to shorten a development period as well as to reduce the mounting area.

A semiconductor device according to one embodiment of the present disclosure includes: a first semiconductor chip; a second semiconductor chip stacked on the first semiconductor chip via a spacer; a first terminal group provided around a stacked body in which the first semiconductor chip and the second semiconductor chip are stacked, and coupled to the first semiconductor chip; a second terminal group provided on an outer side of the first terminal group, and coupled to the second semiconductor chip; and a package member that seals the first semiconductor chip, the second semiconductor chip, the first terminal group, and the second terminal group, and in which at least the first terminal group and the second terminal group are exposed on a back face.

In the semiconductor device according to one embodiment of the present disclosure, the first terminal group coupled to the first semiconductor chip and the second terminal group coupled to the second semiconductor chip are disposed in this order around the stacked body configured by the first semiconductor chip and the second semiconductor chip that are stacked via the spacer, and packaging is achieved with the first terminal group and the second terminal group being exposed on the back face. This allows, for example, a foot pattern formed on a mounting substrate to be shared with a package configured by one semiconductor chip.

### BRIEF DESCRIPTION OF THE DRAWINGS

FIG. 1 is a schematic cross-sectional diagram illustrating one example of a configuration of a semiconductor package according to an embodiment of the present disclosure.

FIG. 2 is a schematic plan diagram illustrating a configuration on a back face side of the semiconductor package illustrated in FIG. 1.

FIG. 3 is a block diagram illustrating one example of a configuration of a receiver having a plurality of demodulation functions.

FIG. 4 is a diagram illustrating one example of a configuration on a mounting substrate in a case where the semiconductor package illustrated in FIG. 1 is used for the receiver having the plurality of demodulation functions illustrated in FIG. 3.

FIG. 5 is a schematic plan diagram on a back face side of a typical semiconductor package.

FIG. 6 is a diagram illustrating a case (A) in which the semiconductor package illustrated in FIG. 1 is mounted on the mounting substrate and a case (B) in which two semiconductor packages are mounted in parallel on the mounting substrate.

FIG. 7A is a schematic plan diagram illustrating the mounting substrate and a foot pattern formed on its surface.

FIG. 7B is a diagram when the semiconductor package illustrated in FIG. 1 is mounted on the mounting substrate illustrated in FIG. 7A.

FIG. 7C is a diagram when the typical semiconductor package illustrated in FIG. 5 is mounted on the mounting substrate illustrated in FIG. 7A.

FIG. 8 is a schematic cross-sectional diagram illustrating one example of a configuration of a semiconductor package according to modification example 1 of the present disclosure.

FIG. 9 is a schematic plan diagram illustrating a configuration on a back face side of the semiconductor package illustrated in FIG. 8.

FIG. 10 is a schematic cross-sectional diagram illustrating one example of a configuration of a semiconductor package according to modification example 2 of the present disclosure.

FIG. 11 is a schematic plan diagram illustrating a configuration on a back face side of the semiconductor package illustrated in FIG. 10.

### MODES FOR CARRYING OUT THE INVENTION

Hereinafter, an embodiment of the present disclosure will be described in detail with reference to the drawings. The following description is a specific example of the present disclosure, but the present disclosure is not limited to the following embodiment. In addition, the present disclosure is not limited to arrangement, dimensions, dimensional ratios, and the like of the constituent elements illustrated in the respective drawings. It is to be noted that the description is given in the following order.

### 1. Embodiment

(an example of a semiconductor package in which a first terminal group coupled to a first semiconductor chip and a second terminal group coupled to a second semiconductor chip are disposed in order from an inner side around a stacked body in which the first semiconductor chip and the second semiconductor chip are stacked in this order)

1-1. Configuration of Semiconductor Package

1-2. Semiconductor Package Manufacturing Method

1-3. Configuration of Receiver

1-4. Workings and Effects

### 2. Modification Examples

2-1. Modification Example 1

(an example of a semiconductor package in which three or more semiconductor chips are stacked)

2-2. Modification Example 2

(an example of a semiconductor package in which a semiconductor chip is stacked on an interposer substrate)

2-3. Modification Example 3

(another example of a configuration of the receiver)

### 1. Embodiment

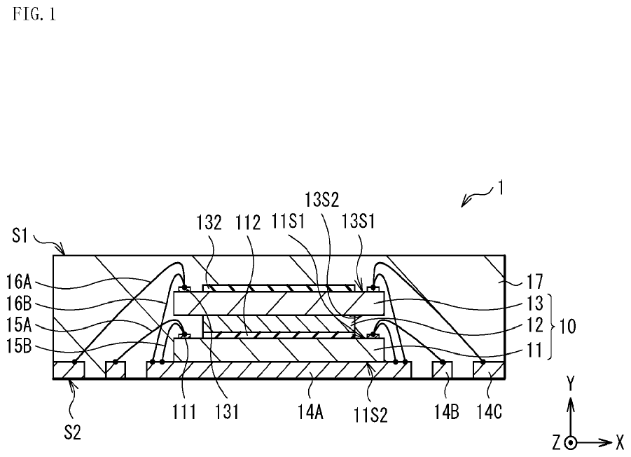

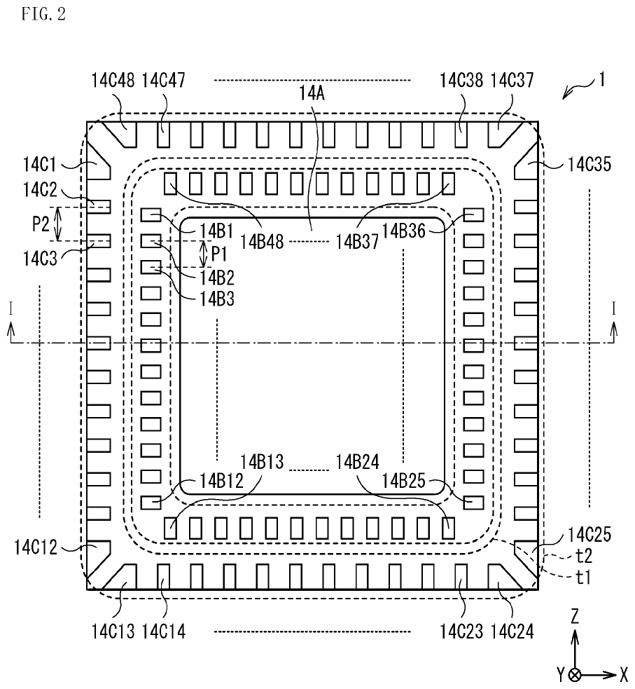

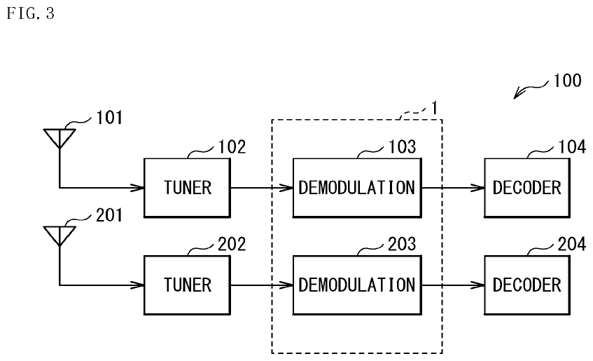

FIG. 1 schematically illustrates one example of a cross-sectional configuration of a semiconductor device (a semiconductor package 1) according to an embodiment of the present disclosure. FIG. 2 illustrates a plan configuration on a back face side of the semiconductor package 1 illustrated in FIG. 1. It should be noted that FIG. 1 illustrates, for example, a cross section taken along the line I-I illustrated in FIG. 2. The semiconductor package 1 is a package in which a plurality of semiconductor chips is stacked and packaged, and is applied to, for example, a system in which functions of multiple systems are desired, such as a digital broadcast demodulation system. In the present embodiment, the semiconductor package 1 of the present disclosure will be described by exemplifying a receiver (a receiver 100) having a plurality of demodulation functions (demodulation circuits 103 and 203) as illustrated in FIG. 3. Note that FIGS. 1 and 2 schematically illustrate a configuration of the semiconductor package 1, and dimensions and shapes can differ from actual dimensions and shapes.

### 1-1. Configuration of Semiconductor Package

In the semiconductor package 1 of the present embodiment, for example, a first terminal group t1 and a second terminal group t2 are provided in this order from an inner side around a stacked body 10 in which two semiconductor chips (a first semiconductor chip 11 and a second semiconductor chip 13) are stacked in this order via a spacer 12. The stacked body 10 is disposed on, for example, a die pad 14A, and the first semiconductor chip 11 and the second semiconductor chip 13 are electrically coupled to the first terminal group t1 and the second terminal group t2 by thin metal lines 15A and 16A, respectively. The first terminal group t1 and the second terminal group t2 are configured by a plurality of pad electrodes 14B and a plurality of pad electrodes 14C, respectively. The present embodiment has a configuration in which the die pad 14A and the plurality of pad electrodes 14B and 14C are exposed on a back face (a face S2) of the semiconductor package 1.

The stacked body 10 includes the first semiconductor chip 11 and the second semiconductor chip 13 that are stacked in this order on the die pad 14A via the spacer 12. The first semiconductor chip 11 and the second semiconductor chip 13 are IC chips having the same function as each other.

On a circuit face (a face 1151) of the first semiconductor chip 11, a plurality of electrodes 111 is disposed, for example, along an outer periphery of the first semiconductor chip 11. Further, an electric circuit (an unillustrated demodulation circuit) having a demodulation function, for example, is formed on the circuit face (the face 11S1) of the first semiconductor chip 11, and is electrically coupled to each of the plurality of electrodes 111 on the circuit face (the face 11S1). On the circuit face (the face 11S1) of the first semiconductor chip 11, a protection film 112 for protecting the electric circuit is further formed on an inner side of the plurality of electrodes on the circuit face (the face 11S1), for example, so as to cover the electric circuit.

On a circuit face (a face 13S1) of the second semiconductor chip 13, a plurality of electrodes 131 is disposed, for example, along an outer periphery of the second semiconductor chip 13. Further, an electric circuit (an unillustrated demodulation circuit) having a demodulation function, for example, is formed on the circuit face (the face 13S1) of the second semiconductor chip 13 as with the first semiconductor chip 11, and is electrically coupled to each of the plurality of electrodes 131 on the circuit face (the face 13S1). On the circuit face (the face 13S1) of the second semiconductor chip 13, a protection film 132 for protecting the electric circuit is further formed on an inner side of the plurality of electrodes 131 on the circuit face (the face 13S1), for example, so as to cover the electric circuit. The second semiconductor chip 13 is stacked on the first semiconductor chip 11 via the spacer 12, with a back face (a face 13S2) on an opposite side of the circuit face (the face 13S1) serving as an opposing surface that faces the circuit face (the face 11 S1) of the first semiconductor chip 11.

The spacer 12 is for forming a gap between the first semiconductor chip 11 and the second semiconductor chip 13, specifically, between the circuit face (the face 11S1) of the first semiconductor chip 11 and the back face (the face 13S2) of the second semiconductor chip 13, in order to couple the plurality of electrodes 111 on the circuit face (the face 11 S1) of the first semiconductor chip 11 and the plurality of pad electrodes 14B configuring the first terminal group t1. As the spacer 12, for example, it is possible to use a silicon rubber or the like.

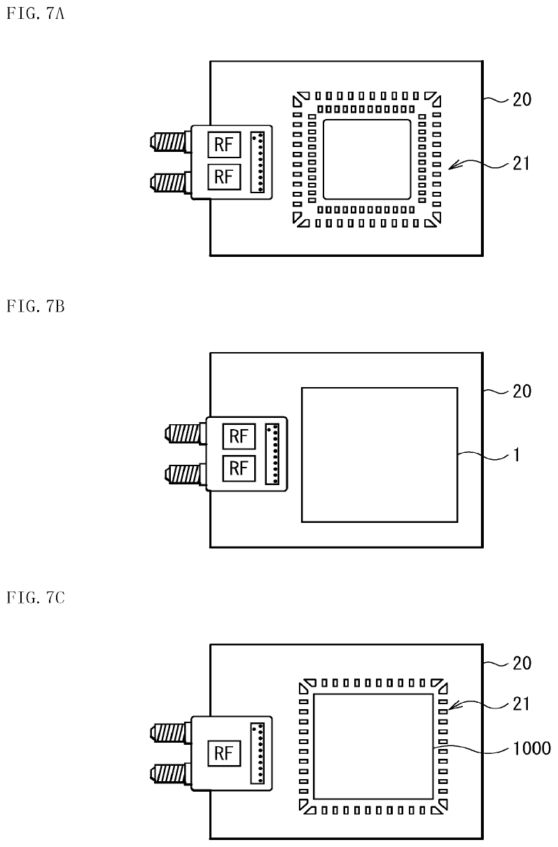

The die pad 14A and the plurality of pad electrodes 14B and 14C generally support and fix a semiconductor element and are formed, for example, by a lead frame. The lead frame supports and fixes the semiconductor chip and is used for a connection with an external wiring line. In the present embodiment, the die pad 14A supports the stacked body 10, and the pad electrodes 14B and 14C are each used as a connection terminal with, for example, a wiring line pattern 21 (a foot pattern) formed on a mounting substrate 20 (see, for example, FIG. 7A). The lead frame is formed using, for example, a copper (Cu) alloy, an iron (Fe) alloy, or any other metal that is excellent in mechanical strength, electrical conductivity, thermal conductivity, corrosion resistance, etc. In the present embodiment, the die pad 14A and the plurality of pad electrodes 14B and 14C are exposed on the back face (the face S2) of the semiconductor package 1, and are mounted on the mounting substrate 20 by soldering and electrically coupled to the wiring line pattern.

The stacked body 10 is bonded to the die pad 14A by, for example, a die-attachment material that is an adhesive for die bonding. The die pad 14A is used, for example, as a common ground for the first semiconductor chip 11 and the second semiconductor chip that configure the stacked body 10. The plurality of electrodes 111 and 131 formed on the circuit face (the face 11 S1) of the first semiconductor chip 11 and the circuit face (the face 13S1) of the second semiconductor chip 13 are electrically coupled to the die pad 14A via thin metal lines 15B and 16B, respectively, as illustrated in FIG. 1, for example. In this manner, by using the die pad 14A as a ground, it is possible to reduce a ground impedance as compared with a case where, for example, the mounting is performed on the mounting substrate 20 using an interposer substrate.

The plurality of pad electrodes 14B and 14C is a package terminal having various functions. The plurality of pad electrodes 14B configures the first terminal group t1, and is electrically coupled to the plurality of electrodes 111 formed on the circuit face (the face 11S1) of the first semiconductor chip 11 via a thin metal line 15A. Similarly, the plurality of pad electrodes 14C configures the second terminal group t2 and is disposed on the outer periphery of the first terminal group t1, and is electrically coupled to the plurality of electrodes 131 formed on the circuit face (the face 13S1) of the second semiconductor chip 13 via a thin metal line 16A.

The first terminal group t1 and the second terminal group t2 are configured by the same number of terminals as each other. For example, in the semiconductor package 1 illustrated in FIG. 2, the first terminal group t1 and the second terminal group t2 are configured by 48 pad electrodes 14B and 14C, respectively. The first terminal group t1 and the second terminal group t2 are disposed such that the terminals having the same function are disposed in the same order as each other. Specifically, for example, 48 pad electrodes 14B and 14C are disposed in the semiconductor package 1 such that 12 pad electrodes are disposed at each of four sides as illustrated in FIG. 2. In a case where the identification numbers (1, 2, 3, . . . , 48) are assigned to the ends of respective reference numerals in order from the upper left side of FIG. 2 for the 48 pieces of pad electrodes 14B and 14C, the pad electrodes 14B and 14C to which the same identification number is assigned have the same function as each other.

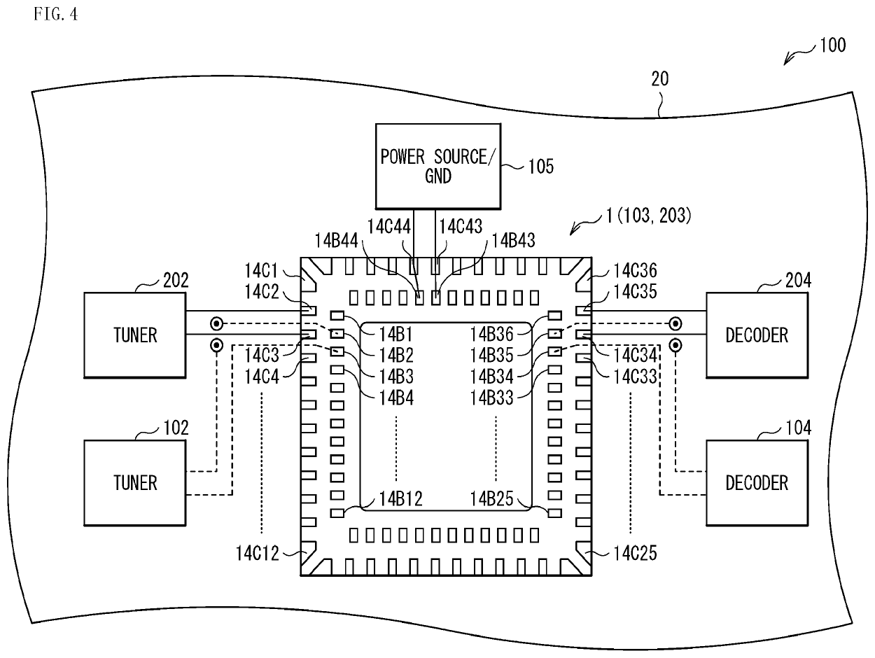

Further, the plurality of pad electrodes 14C configuring the second terminal group t2 is arrayed at a pitch wider than an array pitch of the plurality of pad electrodes 14B configuring the first terminal group t1. In other words, distances between adjacent pad electrode are arrayed such that a distance between the plurality of pad electrodes 14C is greater than a distance between the plurality of pad electrodes 14B. Specifically, for example, a distance P1 from a center part of a pad electrode 14B2 to a center part of an adjacent pad electrode 14B3 and a distance P2 from a center part of a pad electrode 14C2 to a center part of an adjacent pad electrode 14C3 are arrayed such that P1<P2 is satisfied as illustrated in FIG. 2. This makes it possible to lead wiring line patterns of the first terminal group t1 in order from among the plurality of pad electrodes 14C configuring the second terminal group t2, and to achieve a connection with an electric circuit (e.g., a tuner circuit 102) disposed outside the semiconductor package 1 only by the wiring line patterns on a surface (e.g., see FIG. 4). Accordingly, it is possible to simplify the wiring line patterns.

The thin metal lines 15A, 15B, 16A, and 16B are each formed by a wire bonding, and is configured by a gold (Au) thin line, for example.

The stacked body 10, the die pad 14A, surfaces of the plurality of pad electrodes 14B and 14C, and the thin metal lines 15A, 15B, 16A, and 16B are collectively sealed by a package member 17. The package member 17 is configured by, for example, an insulating resin such as an epoxy resin.

### 1-2. Semiconductor Package Manufacturing Method

In the semiconductor package 1, for example, the first semiconductor chip 11 is fixed on the lead frame by the die-attachment material, following which the plurality of electrodes 111 formed on the circuit face (the face 11S1) of the first semiconductor chip 11 and the die pad 14A portions of the lead frame and the plurality of electrodes 111 and the plurality of pad electrode 14B portions are coupled to each other using the thin metal lines 15A and 15B, respectively, by means of a wire bonding method, for example. Subsequently, the spacer 12 is adhered on the electric circuit (specifically, on the protection film 112) formed on the circuit face (the face 11S1) of the first semiconductor chip 11, following which the second semiconductor chip 13 is fixed onto the spacer 12. Next, the plurality of electrodes 131 formed on the circuit face (the face 13S1) of the second semiconductor chip 13 and the die pad 14A portions of the lead frame and the plurality of electrodes 131 and the plurality of pad electrode 14C portions are coupled to each other using the thin metal lines 16A and 16B, respectively, by means of a wire bonding method, for example. Subsequently, a surface of the lead frame is covered with the package member 17 to collectively seal the first semiconductor chip 11, the spacer 12, the second semiconductor chip 13, and the thin metal lines 15A, 15B, 16A, and 16B. Thereafter, the lead frame is detached from a back face side. Thus, the semiconductor package 1 illustrated in FIG. 1 is completed.

### 1-3. Configuration of Receiver

FIG. 4 illustrates one example of a configuration on the mounting substrate 20 in a case where the semiconductor package illustrated in FIG. 1 is used for the receiver 100 having the plurality of demodulation functions illustrated in FIG. 3. The receiver 100 is, for example, a receiver having two systems of receiving systems, and includes antennas 101 and 201, tuner circuits 102 and 202, demodulation circuits 103 and 203, and decoder circuits 104 and 204. FIG. 4 illustrates an exemplary arrangement of the tuner circuits 102 and 202, the demodulation circuits 103 and 203, and the decoder circuits 104 and 204 illustrated in FIG. 3 on the mounting substrate 20. For example, the demodulation circuits 103 and 203 are configured by the semiconductor package 1 of the present embodiment.

In the tuner circuits 102 and 202, reception signals received by the antennas 101 and 201 are each converted into a predetermined frequency to be amplified. The reception signals thus converted and amplified by the tuner circuits 102 and 202 are supplied to the respective demodulation circuits 103 and 203.

In the demodulation circuits 103 and 203, the reception signals supplied from the tuner circuits 102 and 202 are demodulated into pieces of digital data in a predetermined form. The pieces of digital data demodulated by the demodulation circuits 103 and 203 are supplied to the respective decoder circuits 104 and 204.

In the decoder circuits 104 and 204, the pieces of digital data supplied from the demodulation circuits 103 and 203 are decoded.

In the present embodiment, the demodulation circuits 103 and 203 are configured by the semiconductor package 1. That is, in the semiconductor package 1, the demodulation circuit 103 is formed on the circuit face (the face 11S1) of the first semiconductor chip 11, and the demodulation circuit 203 is formed on the circuit face (the face 13S1) of the second semiconductor chip 13. In the first terminal group t1 and the second terminal group t2, input terminals that receive an input of the reception signals supplied from the tuner circuits 102 and 202 and output terminals for supplying the pieces of digital data to the decoder circuits 104 and 204 are respectively disposed in the same order as each other.

Specifically, in the semiconductor package 1, for example, the second and the third pad electrodes 14B2 and 14B3 from the top among the twelve pad electrodes 14B1 to 14B12 disposed along one side of the semiconductor package 1 that faces the tuner circuit 102 in FIG. 4 are allocated as the input terminals (tuner input terminals) that couple the tuner circuit 102 and the demodulation circuit 103. Further, in the semiconductor package 1, for example, the second and the third pad electrodes 14C2 and 14C3 from the top among the twelve pad electrodes 14C1 to 14C12 disposed along the one side of the semiconductor package 1 that faces the tuner circuit 202 in FIG. 4 are allocated as the input terminals that couple the tuner circuit 202 and the demodulation circuit 203, as with the pad electrodes 14B1 to 14B12. As illustrated in FIG. 4, the wiring line patterns that couple the tuner circuit 102 and the pad electrodes 14B2 and 14B3 are lead from between the pad electrode 14C2 and the pad electrode 14C3, and from between the pad electrode 14C3 and the pad electrode 14C4, respectively.

Further, in the semiconductor package 1, for example, the tenth and the eleventh pad electrodes 14B34 and 14B35 from the bottom among the twelve pad electrodes 14B25 to 14B36 disposed along one side of the semiconductor package 1 that faces the decoder circuit 104 in FIG. 4 are allocated as the output terminals that couple the decoder circuit 104 and the demodulation circuit 103. Further, in the semiconductor package 1, for example, the tenth and the eleventh pad electrodes 14C34 and 14C35 from the bottom among the twelve pad electrodes 14C25 to 14C36 disposed along the one side of the semiconductor package 1 that faces the decoder circuit 204 in FIG. 4 are allocated as the output terminals (decoder output terminals) that couple the decoder circuit 204 and the demodulation circuit 203, as with the pad electrodes 14B25 to 14B36. As illustrated in FIG. 4, the wiring line patterns that couple the decoder circuit 104 and the pad electrodes 14B34 and 14B35 are lead from between the pad electrode 14C33 and the pad electrode 14C34, and from between the pad electrode 14C34 and the pad electrode 14C35, respectively.

Further, as illustrated in FIG. 4, a power source/ground (GND) circuit 105 is formed on the mounting substrate 20. The power source/ground (GND) circuit 105 and the demodulation circuits 103 and 203 are coupled to the seventh and the eighth pad electrodes 14B43, 14B44, 14C43, and 14C44 from the right among the twelve pad electrodes 14B37 to 14B48 and 14C37 to 14C48 disposed along one side that faces the power source/ground (GND) circuit 105 in FIG. 4, for example. It should be noted that it is possible to allow connection wiring lines between the power source/ground (GND) circuit 105 and the pad electrodes 14B43 and 14B44 and connection wiring lines between the power source/ground (GND) circuit 105 and the pad electrodes 14C43 and 14C44 to be common. As illustrated in FIG. 4, the power source/ground (GND) circuit 105 and the pad electrodes 14B43 and 14C43 and the power source/ground (GND) circuit 105 and the pad electrodes 14B44 and 14C44 are coupled by the common wiring line patterns.

### 1-4. Workings and Effects

In the semiconductor package 1 of the present embodiment, the first terminal group t1 and the second terminal group t2 are provided in order from the inner side around the stacked body 10 in which the first semiconductor chip 11 and the second semiconductor chip 13 are stacked. Specifically, the first terminal group t1 electrically coupled to the first semiconductor chip 11 is provided around the stacked body 10, and the second terminal group t2 electrically coupled to the second semiconductor chip 13 is provided on the outer periphery of the first terminal group t1. In addition, the first semiconductor chip 11, the second semiconductor chip 13, the first terminal group t1, and the second terminal group are collectively sealed from the surface by the package member 17, and the first terminal group t1 and the second terminal group are exposed on the back face (the back face (the face S2) of the semiconductor package 1) of the package member 17. This allows, for example, the foot pattern (the wiring line pattern 21) formed on the mounting substrate 20 to be shared with the semiconductor package configured by, for example, one semiconductor chip (see, e.g., FIG. 7A to FIG. 7C). This will be described below.

As described above, in recent years, there has been an increasing tendency that a plurality of tuners and a plurality of demodulation functions are mounted on a digital broadcast receiver. In order to address multiple systems, it is necessary to dispose a plurality of corresponding semiconductor chips and the mounting area tends to become large accordingly. Further, because it is necessary to design a system of various system numbers in accordance with the demanded specification, such as one system, two systems, or three systems or more, it takes time to design a layout suitable for each system.

As a method for solving the above-described problem, a method of using a single semiconductor chip having a plurality of demodulation functions or a method of achieving packaging by stacking or arranging, on an interposer substrate, a plurality of semiconductor chips having a demodulation function of one system is conceivable. However, the former necessitates a development of a single semiconductor chip having demodulation functions of multiple systems on the basis of demanded specification, making it difficult to address flexibly. In addition, the latter increases a packaging cost by the interposer substrate and raises a problem in which a manufacturing cost increases as compared with the semiconductor package having a single system.

In contrast, in the semiconductor package 1 of the present embodiment, the second semiconductor chip 13 is stacked on the first semiconductor chip 11 via the spacer 12. The first terminal group t1 configured by the plurality of pad electrodes 14B electrically coupled to the first semiconductor chip 11 and the second terminal group t2 configured by the plurality of pad electrodes 14C electrically coupled to the second semiconductor chip 13 are disposed in order from the inner side around the stacked body 10. These are packaged by sealing them collectively from the surface by the package member 17.

FIG. 5 schematically illustrates a plane on a back face side of a semiconductor package 1000 having a single demodulation function as a comparative example of the semiconductor package 1 of the present embodiment. In a typical semiconductor package 1000, a semiconductor chip 1011 is fixed on a die pad 1014A configured by a lead frame 1014, and a plurality of pad electrodes 1014B configured by the lead frame 1014 is disposed around the die pad 1014A along each side of the semiconductor package 1000 as external lead-out terminals of respective electrodes formed on a circuit face of the semiconductor chip 1011.

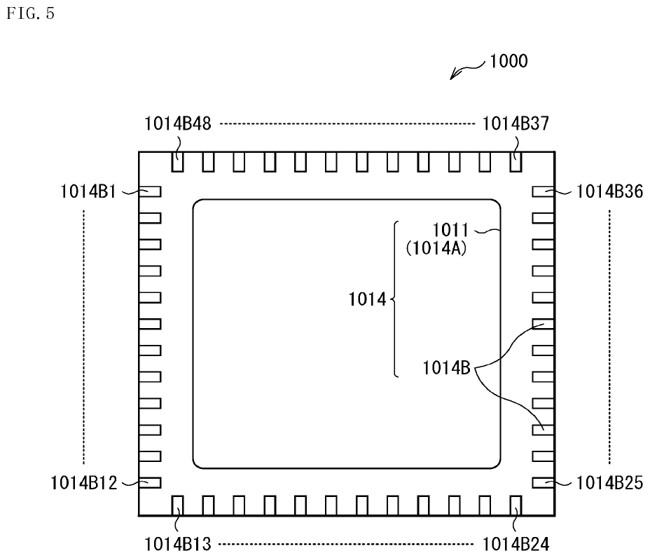

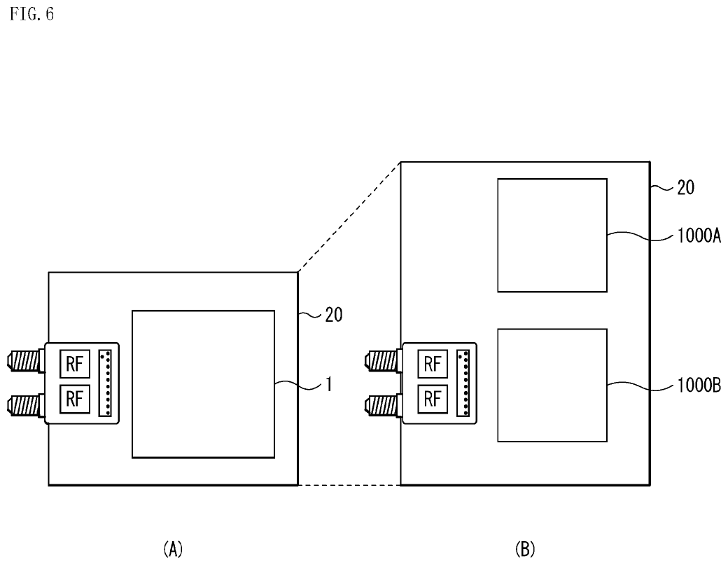

FIG. 6 illustrates a case (A) in which the semiconductor package 1 of the present embodiment is mounted on the mounting substrate 20, and a case (B) in which, for example, a semiconductor package 1000A and a semiconductor package 1000B, in which the first semiconductor chip 11 and the first terminal group t1 and the second semiconductor chip 13 and the second terminal group t2 are separately packaged, respectively, as with the semiconductor package 1000 illustrated in FIG. 5, are mounted in parallel on the mounting substrate 20. The outer shapes of the semiconductor packages 1000A and 1000B having a function of a single system in which the first semiconductor chip 11 and its terminal group (the first terminal group t1) and the second semiconductor chip 13 and its terminal group (the second terminal group t2) are individually packaged respectively as with the semiconductor package 1000 are, for example, 7 mm×7 mm. In a case where these two semiconductor packages 1000A and 1000B are mounted in parallel as illustrated in (B) of FIG. 6, the mounting area is 98 mm². In contrast, as illustrated in (A) of FIG. 6, the outer shape of the semiconductor package in which the packaging is achieved by stacking, for example, two semiconductor chips (the first semiconductor chip 11 and the second semiconductor chip 13) and disposing the corresponding terminal groups (the first terminal group t1 and the second terminal group t2) around the stack is increased by, for example, the terminal group disposed on the outer side, for example, 9×9 mm, and the mounting area thereof is 81 mm². That is, it is possible to reduce the mounting area by about 20% as compared with a case where two semiconductor packages 1000A and 1000B are mounted in parallel.

In the semiconductor package 1 of the present embodiment, the stacked body 10 in which the first semiconductor chip 11 and the second semiconductor chip 13 are stacked is fixed on the die pad 14A. Further, the die pad 14A and the array of the plurality of pad electrodes 14B configuring the first terminal group t1 on the inner side among the terminal groups disposed around the die pad 14A has the same array as a terminal array (the plurality of pad electrodes 1014B) of the semiconductor package 1000. That is, the plurality of pad electrodes 14B and the plurality of pad electrodes 1014B have the same function for each identification number (1, 2, 3, . . . , 48) assigned to the end of each reference numeral. Accordingly, the die pad 14A and the terminal array of the first terminal group t1 exposed on the back face (the face S2) side of the semiconductor package 1 of the present embodiment and the terminal array on the back face side of the semiconductor package 1000 are compatible with a foot pattern (for example, the wiring line pattern 21 illustrated in FIG. 7A) formed on the mounting substrate.

FIG. 7A illustrates one example of the mounting substrate 20 in which the wiring line pattern 21 (the foot pattern) corresponding to the semiconductor package 1 is formed. FIG. 7B illustrates a plan configuration when the semiconductor package 1 is mounted on the wiring line pattern 21 illustrated in FIG. 7A. FIG. 7C illustrates a plan configuration when the semiconductor package 1000 is mounted on the wiring line pattern 21 illustrated in FIG. 7A. As described above, the terminal array of the first terminal group t1 on the inner side of the semiconductor package 1 of the present embodiment is identical to the terminal array of the semiconductor package 1000. Thus, it is possible to share the wiring line pattern 21 formed on the mounting substrate 20 as illustrated in FIG. 7B and FIG. 7C.

As described above, in the semiconductor package 1 of the present embodiment, the first terminal group t1 electrically coupled to the first semiconductor chip 11 and the second terminal group t2 electrically coupled to the second semiconductor chip 13 are disposed in order around the stacked body 10 configured by the first semiconductor chip 11 and the second semiconductor chip 13 stacked in order via the spacer 12, and the packaging is achieved by the package member 17. Thus, it is possible to reduce the mounting area as compared with a case where respective semiconductor chips are mounted in parallel. In addition, in the semiconductor package 1, the first terminal group t1 electrically coupled to the first semiconductor chip 11 and the second terminal group t2 electrically coupled to the second semiconductor chip 13 are disposed in order from the inner side in the stacking order of the first semiconductor chip 11 and the second semiconductor chip 13. This allows a wiring line pattern (e.g., the wiring line pattern 21) formed on the mounting substrate to be shared with a semiconductor package of a single system (e.g., the semiconductor package 1000) that has, for example, the same function as the semiconductor package 1. Accordingly, it is possible to selectively use, depending on the number of systems necessary for a system, the semiconductor package having a single system mounted on one mounting substrate and the semiconductor package having multiple systems mounted on one mounting substrate, and thereby to reduce a development period. In addition, it is possible to reduce a development cost of a system.

Further, in the semiconductor package 1 of the present embodiment, the semiconductor chips (the first semiconductor chip 11 and the second semiconductor chip 13) having the same function (equivalent or identical function) as each other are stacked on each other. Thus, it becomes unnecessary to develop a semiconductor chip corresponding to multiple systems. Accordingly, it is possible to further shorten the development period and further reduce the development cost.

Further, it is possible to reduce the ground impedance as compared with a case where the interposer substrate is used. Further, it is possible to improve heat dissipation. Accordingly, it is possible to allow for the use in the same temperature range as the conventional case even in a case where the package is miniaturized. Furthermore, because the designing of the interposer substrate is not necessary as well, it is possible to further shorten the development period and to further reduce the development cost as well.

Next, modification examples 1 to 3 of the present disclosure will be described. Hereinafter, the similar components to those of the embodiment described above are denoted by the same reference numerals, and description thereof is omitted as appropriate.

### 2. Modification Examples

### 2-1. Modification Example 1

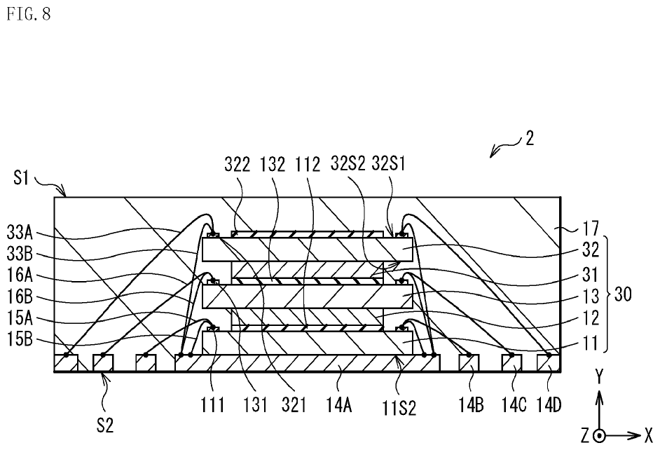

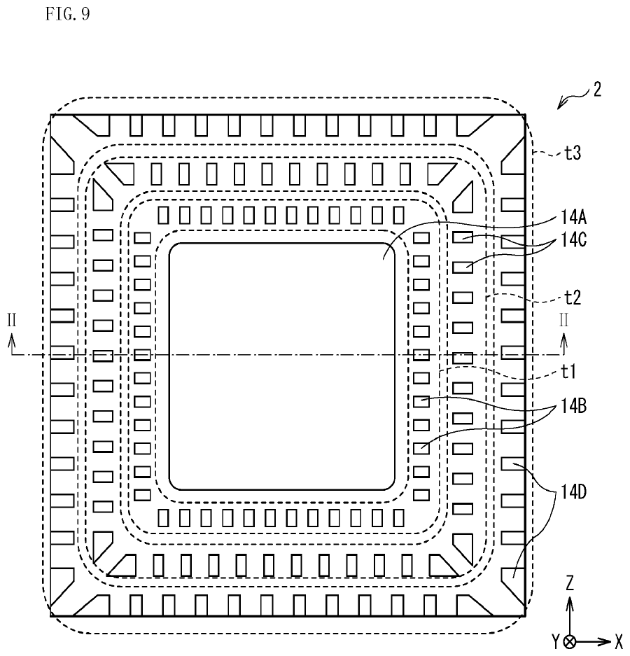

FIG. 8 schematically illustrates one example of a cross-sectional configuration of a semiconductor device (a semiconductor package 2) according to the modification example 1 of the present disclosure. FIG. 9 illustrates a plan configuration on a back face side of the semiconductor package 2 illustrated in FIG. 1. It should be noted that FIG. 8 illustrates, for example, a cross section taken along the line II-II illustrated in FIG. 9. The semiconductor package 2 is a package in which a plurality of semiconductor chips is stacked and packaged, and is applied to, for example, a system in which functions of multiple systems are desired, such as a digital broadcast demodulation system, as with the embodiment described above. The semiconductor package 2 of the present modification example differs from the embodiment described above, in that three semiconductor chips are stacked.

In the semiconductor package 2 of the present modification example, for example, three semiconductor chips (the first semiconductor chip 11, the second semiconductor chip 13, and a third semiconductor chip 32) are stacked in this order via the spacer 12 and a spacer 31, and the first terminal group t1, the second terminal group t2, and a third terminal group t3 are provided in order from the inner side to an outer side around a stacked body 30 thereof. The stacked body 30 is disposed on, for example, the die pad 14A, and the first semiconductor chip 11, the second semiconductor chip 13, and the third semiconductor chip 32 are electrically coupled to the first terminal group t1, the second terminal group t2, and the third terminal group t3 by the thin metal lines 15A, 16A, and 33A, respectively. The third terminal group t3 is configured by a plurality of pad electrodes 14D as with the first terminal group t1 and the second terminal group t2. The semiconductor package 2 has a configuration in which the plurality of pad electrodes 14D is exposed on the back face (the face S2) of the semiconductor package 2 together with the die pad 14A and the plurality of pad electrodes 14B and 14C.

On a circuit face (a face 32S1) of the third semiconductor chip 32, a plurality of electrodes 321 is disposed, for example, along an outer periphery of the third semiconductor chip 32. Further, an electric circuit (an unillustrated demodulation circuit) having a demodulation function, for example, is formed on the circuit face (the face 32S1) of the third semiconductor chip 32, and is electrically coupled to each of the plurality of electrodes 321 on the circuit face (the face 32S1), as with the first semiconductor chip 11. On the circuit face (the face 32S1) of the third semiconductor chip 32, a protection film 322 for protecting the electric circuit is further formed on an inner side of the plurality of electrodes 321 on the circuit face (the face 32S1), for example, so as to cover the electric circuit.

Further, the third semiconductor chip 32 is stacked on the second semiconductor chip 13 via the spacer 31, with a back face (a face 32S2) on an opposite side of the circuit face (the face 32S1) serving as an opposing surface that faces the circuit face (the face 13S1) of the second semiconductor chip 13. The die pad 14A of the present modification example is used, for example, as a common ground for the first semiconductor chip 11, the second semiconductor chip, and the third semiconductor chip 32 as with the embodiment described above. The plurality of electrodes 321 formed on the circuit face (the face 32S1) of the third semiconductor chip 32 is electrically coupled to the die pad 14A via a thin metal line 33B as with the plurality of electrodes 111 and 131 of the first semiconductor chip 11 and the second semiconductor chip 13.

As described above, the present technology is not limited to a case where two semiconductor chips (the first semiconductor chip 11 and the second semiconductor chip 13) are stacked as with the semiconductor package 1 of the embodiment described above, and is applicable to a case where three semiconductor chips are stacked as well, in which case it is possible to achieve effects similar to those of the embodiment described above.

It should be noted that that the number of stacks of the semiconductor chips is not limited thereto. It is possible to stack four or more semiconductor chips as well similarly, in which case it is possible to achieve effects similar to those of the embodiment described above.

### 2-2. Modification Example 2

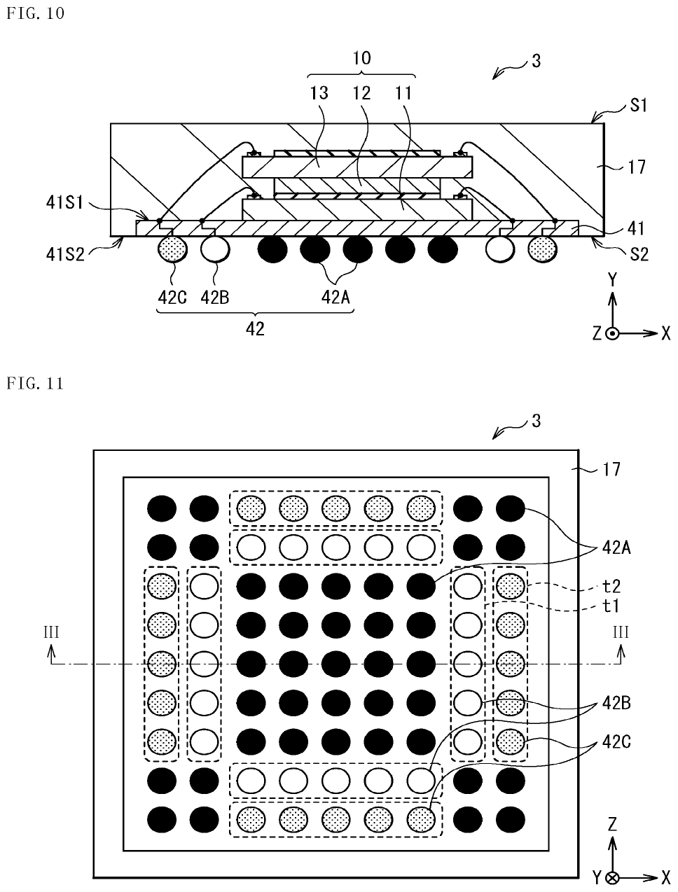

FIG. 10 schematically illustrates one example of a cross-sectional configuration of a semiconductor device (a semiconductor package 3) according to the modification example 2 of the present disclosure. FIG. 11 illustrates a plan configuration on a back face side of the semiconductor package 3 illustrated in FIG. 10. It should be noted that FIG. 10 illustrates, for example, a cross section taken along the line III-III illustrated in FIG. 11. The semiconductor package 3 is a package in which a plurality of semiconductor chips is stacked and packaged, and is applied to, for example, a system in which functions of multiple systems are desired, such as a digital broadcast demodulation system, as with the embodiment described above. The semiconductor package 3 of the present modification example differs from the embodiment and the like described above, in that an interposer substrate 41 is used.

In the semiconductor package 3 of the present modification example, for example, the stacked body 10 illustrated in FIG. 1 is mounted on a surface (a face 41S1) of the interposer substrate 41. The interposer substrate 41 is used for relaying between a semiconductor chip and a substrate that are different from each other in terminal pitch and for making an electrical continuity. On one face (the face 41S1) of the interposer substrate, the first terminal group t1 and the second terminal group t2 are provided in this order from an inner side. In the present modification example, on a back face (a face 41S2) of the interposer substrate 41, the first terminal group t1 and the second terminal group t2 are taken out via through electrodes, and solder balls 42 are used as connection terminals with the wiring line pattern (the foot pattern) formed on the mounting substrate.

It should be noted that, on the back face (the face 41S2) of the interposer substrate 41, the first terminal group t1 electrically coupled to the first semiconductor chip 11 and the second terminal group t2 electrically coupled to the second semiconductor chip 13 are taken out such that terminals that are same in number and having the same function are in the same order, as with the embodiment described above. Specifically, as illustrated in FIG. 11, for example, 9×9 pieces of connection terminals (the solder balls 42) are disposed substantially uniformly on the back face (the face 41S2) of the interposer substrate 41. Among them, for example, 5×5 pieces of connection terminals in the middle and 2×2 pieces of connection terminals (solder balls 42A) at the four corners are used as the connection terminals with the ground. Of the remaining connection terminals, 20 pieces of connection terminals (solder balls 42B) on the inner side are used as the first terminal group t1 for connection with the first semiconductor chip 11, and 20 pieces of connection terminals (solder balls 42C) on the outer side are used as the second terminal group t2 for connection with the second semiconductor chip 13.

As described above, the present technology is also applicable to a case where the interposer substrate 41 is used as with the present modification example, in which case it is possible to achieve effects similar to those of the embodiment described above.

Further, by using the interposer substrate 41, an effect is achieved, in addition to the effects of the embodiment described above, in which a degree of freedom of a terminal array is improved when, for example, a terminal other than the first terminal group t1 and the second terminal group t2, for example, another IC or the like is mounted on a one-chip.

### 2-3. Modification Example 3

In the embodiment described above, for example, in FIG. 4, an example is illustrated in which the tuners (the tuner circuits 102 and 202) and the decoders (the decoder circuits 104 and 204) are built in the receiver 100, but the tuners and the decoders do not necessarily have to be built in the receiver 100.

Although the embodiment and the modification examples have been described above, the content of the present disclosure is not limited to the embodiment and the like described above, and various modifications can be made.

It should be noted that it is possible for the present disclosure to employ the following configurations as well. According to the present technology of the following configurations, the first terminal group coupled to the first semiconductor chip and the second terminal group coupled to the second semiconductor chip are disposed in this order around the stacked body in which the first semiconductor chip and the second semiconductor chip are stacked, and the packaging is achieved with the first terminal group and the second terminal group being exposed on the back face. This allows, for example, the foot pattern formed on the mounting substrate to be shared with a package configured by one semiconductor chip. Accordingly, it is possible to reduce the mounting area and to shorten the development period as compared with a case where a plurality of semiconductor chips is disposed side by side on the mounting substrate. It is to be noted that the effects described herein are not necessarily limiting, and any of the effects described in the present disclosure may be provided.

(1)

A semiconductor device including:

a first semiconductor chip;

a second semiconductor chip stacked on the first semiconductor chip via a spacer;

a first terminal group provided around a stacked body in which the first semiconductor chip and the second semiconductor chip are stacked, and coupled to the first semiconductor chip;

a second terminal group provided on an outer side of the first terminal group, and coupled to the second semiconductor chip; and

a package member that seals the first semiconductor chip, the second semiconductor chip, the first terminal group, and the second terminal group, and in which at least the first terminal group and the second terminal group are exposed on a back face.

(2)

The semiconductor device according to (1), in which the first terminal group and the second terminal group are configured by a plurality of terminals same in number as each other.

(3)

The semiconductor device according to (1) or (2), in which the first terminal group and the second terminal group are disposed such that terminals having the same function are disposed in the same order as each other.

(4)

The semiconductor device according to (3), in which the first terminal group and the second terminal group each include various input terminals and various output terminals, and the input terminals having the same function and the output terminals having the same function are disposed in the same order as each other.

(5)

The semiconductor device according to any one of (2) to (4), in which an array pitch of the plurality of terminals configuring the second terminal group is wider than an array pitch of the plurality of terminals configuring the first terminal group.

(6)

The semiconductor device according to any one of (1) to (5), in which the first semiconductor chip is disposed on a die pad, and the die pad is exposed on the back face of the package member.

(7)

The semiconductor device according to (6), in which the die pad is used as a common ground for the first semiconductor chip and the second semiconductor chip.

(8)

The semiconductor device according to (6) or (7), in which the first terminal group, the second terminal group, and the die pad are configured by a lead frame.

(9)

The semiconductor device according to any one of (1) to (8), in which the first semiconductor chip and a plurality of terminals configuring the first terminal group are electrically coupled using a thin metal line, and the second semiconductor chip and a plurality of terminals configuring the second terminal group are electrically coupled using a thin metal line.

(10)

The semiconductor device according to any one of (1) to (9), further including a third semiconductor chip and a third terminal group coupled to the third semiconductor chip, in which

the third semiconductor chip is stacked on the second semiconductor chip via a spacer, and

the third terminal group is provided on an outer side of the second terminal group.

(11)

The semiconductor device according to any one of (1) to (10), further including an interposer substrate, in which

the first semiconductor chip is stacked on one face of the interposer substrate, and

the first terminal group and the second terminal group are provided on another face of the interposer substrate that is on an opposite side of the one face.

The present application claims the benefit of Japanese Priority Patent Application JP2019-110760 filed with the Japan Patent Office on Jun. 14, 2019, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a first semiconductor chip;
a second semiconductor chip stacked on the first semiconductor chip via a spacer;
a first terminal group provided around a stacked body in which the first semiconductor chip and the second semiconductor chip are stacked, and coupled to the first semiconductor chip;
a second terminal group provided on an outer side of the first terminal group, and coupled to the second semiconductor chip, wherein terminals having a same function as those of the first terminal group are disposed in a same order as those of the first terminal group; and
a package member that seals the first semiconductor chip, the second semiconductor chip, the first terminal group, and the second terminal group, and in which at least the first terminal group and the second terminal group are exposed on a back face.

2. The semiconductor device according to claim 1, wherein the first terminal group and the second terminal group are configured by a plurality of terminals same in number as each other.

3. (canceled)

4. The semiconductor device according to claim 1, wherein the first terminal group and the second terminal group each include various input terminals and various output terminals, and the input terminals having a same function and the output terminals having a same function are disposed in a same order as each other.

5. The semiconductor device according to claim 2, wherein an array pitch of the plurality of terminals configuring the second terminal group is wider than an array pitch of the plurality of terminals configuring the first terminal group.

6. The semiconductor device according to claim 1, wherein the first semiconductor chip is disposed on a die pad, and the die pad is exposed on the back face of the package member.

7. The semiconductor device according to claim 6, wherein the die pad is used as a common ground for the first semiconductor chip and the second semiconductor chip.

8. The semiconductor device according to claim 6, wherein the first terminal group, the second terminal group, and the die pad are configured by a lead frame.

9. The semiconductor device according to claim 1, wherein the first semiconductor chip and a plurality of terminals configuring the first terminal group are electrically coupled using a thin metal line, and the second semiconductor chip and a plurality of terminals configuring the second terminal group are electrically coupled using a thin metal line.

10. The semiconductor device according to claim 1, further comprising a third semiconductor chip and a third terminal group coupled to the third semiconductor chip, wherein
the third semiconductor chip is stacked on the second semiconductor chip via a spacer, and
the third terminal group is provided on an outer side of the second terminal group.

11. The semiconductor device according to claim 1, further comprising an interposer substrate, wherein
the first semiconductor chip is stacked on one face of the interposer substrate, and
the first terminal group and the second terminal group are provided on another face of the interposer substrate that is on an opposite side of the one face.
